(19) United States
(12) Patent Application Publication
(10) Pub. No.: US 2024/0098891 A1
(43) Pub. Date: Mar. 21, 2024

(54) CIRCUIT BOARD FOR HIGH FREQUENCY DEVICES, AND HIGH FREQUENCY DEVICE

(71) Applicant: AGC Inc., Tokyo (JP)

(72) Inventors: Takeyuki KATO, Tokyo (JP); Yutaka KUROIWA, Tokyo (JP); Nobuo INUZUKA, Shizuoka (JP); Hirofumi YAMAMOTO, Shizuoka (JP)

(73) Assignee: AGC Inc., Tokyo (JP)

(21) Appl. No.: 18/520,642

(22) Filed: Nov. 28, 2023

Related U.S. Application Data
(63) Continuation of application No. PCT/JP2022/021432, filed on May 25, 2022.

(30) Foreign Application Priority Data
Jun. 3, 2021 (JP) 2021-093784

(51) Int. Cl. H05K 1/03; H05K 1/02

(52) U.S. Cl. CPC H05K 1/0306; H05K 1/0243; H05K 1/0251; H01L 23/15

(57) ABSTRACT

The present invention relates to a circuit board for a high-frequency device, including: a glass substrate in which a crystal is precipitated and cuttable by etching, and which has a dielectric loss tangent at 20° C. and 10 GHz of 0.0090 or less, and relates to a high-frequency device including the circuit board.

### CROSS-REFERENCE TO RELATED APPLICATIONS

This is a continuation of International Application No. PCT/JP2022/021432 filed on May 25, 2022, and claims priority from Japanese Patent Application No. 2021-093784 filed on Jun. 3, 2021, the entire content of which is incorporated herein by reference.

### TECHNICAL FIELD

The present invention relates to a circuit board for a high-frequency device and a high-frequency device, and more particularly to a circuit board for a high-frequency device including a glass substrate and a high-frequency device including the same.

### BACKGROUND ART

In recent years, wireless transmission using a high-frequency band, such as a microwave band or a millimeter wave band, has attracted attention as a large-capacity transmission technique. Although a high-frequency device is used for wireless transmission in a high-frequency band, a circuit board used in the device is required to reduce transmission loss based on dielectric loss, conductor loss, and the like in order to ensure characteristics such as quality and strength of a high-frequency signal.

In related art, a transmission line such as a microstrip line is used for wiring on a circuit board, but basically no special processing is applied to a dielectric that constitutes the circuit board. However, it is expected that a 3D structure is required for the dielectric in order to cope with further increases in high-frequencies and advancements in techniques in the future.

For example, in a substrate integrated waveguide (SIW) in which a waveguide is formed by a drilling process or in a passive device, a high-frequency device requiring a 3D-processed substrate, such as a through hole, a hollowed-out structure, and a hollow structure, is required in the future from viewpoints of miniaturization, improvement in high-frequency performance, improvement in heat dissipation, and other various aspects.

Patent Literature 1 discloses an example of a substrate integrated waveguide (SIW). This literature describes ceramics (glass ceramics, alumina ceramics, aluminum nitride ceramics, and the like) and resin materials (liquid crystal polymer, fluororesin, FR4, and the like) as dielectric layers of SIW.

### CITATION LIST

### Patent Literature

[Patent Literature 1] WO2010/114079

### SUMMARY OF THE INVENTION

### Technical Problem

In the related art, as a substrate material of a 3D device for high-frequency, a resin substrate such as a fluorine-based resin (PTFE) or a liquid crystalline polymer (LCP), or a ceramic substrate such as a low-temperature fired laminated ceramic substrate (LTCC) has been used.

However, the fluorine-based resin such as PTFE has a problem of fairly poor processability. Since LCP has poor heat resistance and high thermoplasticity, defects are likely to occur in high-temperature treatment during substrate manufacturing, and problems remain in terms of cost as well as a yield in a molding process. Further, since the ceramic substrate such as LTCC has poor plate formability, it is difficult to form a substrate. Therefore, there is a problem in using any of the above materials as a substrate material for of a 3D device for high-frequency.

Therefore, an object of the present invention is to provide a circuit board for a high-frequency device having excellent processing characteristics and low loss.

### Solution to Problem

As a result of studies aimed at solving the above problems, the present inventors have found that the above problems can be solved by the following configuration.
[1] A circuit board for a high-frequency device, including: a glass substrate in which a crystal is precipitated and cuttable by etching, and which has a dielectric loss tangent at 20° C. and 10 GHz of 0.0090 or less.
[2] The circuit board according to [1], in which a signal having a frequency of 1 GHz to 100 GHz is transmitted.
[3] The circuit board according to [1] or [2], in which the glass substrate has at least one stereoscopic structure of a through hole, a hollowed-out structure, and a hollow structure.
[4] The circuit board according to any one of [1] to [3], further including: a transmission line.
[5] The circuit board according to any one of [1] to [4], further including: at least one of a passive device and an active device.
[6] A high-frequency device including the circuit board according to any one of [1] to [5].

### Advantageous Effects of Invention

A material used for a circuit board of a high-frequency device in the related art has poor processing characteristics even if the material is excellent in dielectric loss, so that a desired 3D structure cannot be obtained. On the other hand, the circuit board according to the present invention includes a specific glass substrate, and thus is excellent in processing characteristics such as 3D-processing and can achieve low transmission loss.

Further, the glass substrate is excellent in plate formability, heat resistance, mechanical characteristics, and the like compared with other materials. The glass substrate can also be easily formed into a substrate, can withstand high-temperature treatment, and has sufficient rigidity as a substrate.

Further, in the related art, it is necessary to change a processing method according to a shape, a size, and the like of a desired substrate. On the other hand, in the circuit board according to the present invention, since the glass substrate can be etched, various 3D structures can be achieved. Specifically, not only general microfabrication shape (a through hole, a hollowed-out structure, or the like), but also complicated microfabrication shape (for example, a spiral shape) can be achieved. Therefore, a circuit board having a wide 3D shape without greatly changing a manufacturing process can be provided.

### BRIEF DESCRIPTION OF DRAWINGS

FIG. 1 is a cross-sectional view illustrating an example of a circuit board for a high-frequency device according to an embodiment of the present invention.

FIG. 2 is a diagram schematically illustrating a hollow structure.

FIG. 3 is a cross-sectional view schematically illustrating a state in which a wiring layer is formed on a glass substrate. (a) of FIG. 3 illustrates a state in which a wiring layer 30 is formed on a glass substrate 31. (b) of FIG. 3 illustrates a state in which hollowed-out portions 32 are formed by performing microfabrication on the glass substrate 31.

FIG. 4 is a graph plotting a relation between relative permittivity and transmission loss in glass substrates according to Example.

FIG. 5 is a graph plotting a relation between a dielectric loss tangent and the transmission loss in the glass substrates according to Example.

### DESCRIPTION OF EMBODIMENTS

Hereinafter, an embodiment of the present invention will be described.

In the present description, “to” indicating a numerical range is used in the sense of including the numerical values set forth before and after the “to” as a lower limit value and an upper limit value, unless otherwise specified.

In the present description, “high-frequency” means a frequency of 1 GHz or more. The high-frequency is preferably 5 GHz or more, more preferably 10 GHz or more, even more preferably 20 GHz or more, particularly preferably 28 GHz or more, and most preferably 35 GHz or more. Further, the high-frequency is, for example, 100 GHz or less.

### Circuit Board

A circuit board for a high-frequency device (hereinafter, also simply referred to as a circuit board) according to one embodiment of the present invention includes a glass substrate in which a crystal is precipitated and cuttable by etching, and which has a dielectric loss tangent at 20° C. and 10 GHz of 0.0090 or less.

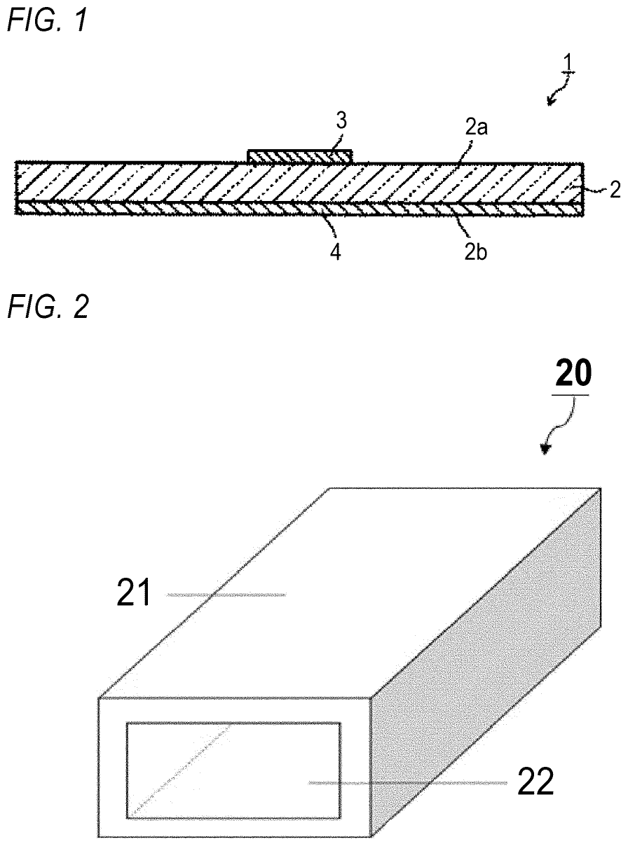

FIG. 1 illustrates an example of a structure of the circuit board according to the present embodiment. A circuit board 1 illustrated in FIG. 1 includes a glass substrate 2 having insulating properties, a first wiring layer 3 formed on a first main surface 2a of the glass substrate 2, and a second wiring layer 4 formed on a second main surface 2b of the glass substrate 2. The first wiring layer 3 and the second wiring layer 4 form a microstrip line as an example of a transmission line. The first wiring layer 3 constitutes a signal wiring, and the second wiring layer 4 constitutes a ground wiring.

However, the structures of the first wiring layer 3 and the second wiring layer 4 are not limited to those described above. The wiring layer may be formed on only one main surface of the glass substrate 2, or may be formed not on the main surface of the glass substrate 2 but inside the glass substrate 2. Further, the circuit board according to the present embodiment may include other components not illustrated in FIG. 1.

As described above, the circuit board according to the present embodiment may be a circuit board including a glass substrate and a wiring layer formed inside the glass substrate or on at least one main surface of the glass substrate.

### Glass Substrate

Hereinafter, the glass substrate included in the circuit board according to the present embodiment will be described. In the glass substrate, a crystal is precipitated and cuttable by etching, and dielectric loss tangent at 20° C. and 10 GHz is 0.0090 or less.

The glass substrate is an insulating substrate formed by, as a material, a glass in which a crystal is precipitated and cuttable by etching. A type of glass used as the material is not particularly limited as long as the glass has the above characteristics. Examples of the glass include a photosensitive glass.

As generally known, the photosensitive glass refers to a glass that allows microfabrication by precipitating a crystal by exposure and heat treatment and removing the crystal by etching. More specifically, the photosensitive glass can selectively precipitate a crystal on a mask-exposed portion by controlling a pattern of a portion to be exposed by a mask and then performing heat treatment. Further, since the crystal precipitated by exposure and heat treatment have a fairly high solubility in hydrofluoric acid, the crystal can be removed and processed by hydrofluoric acid etching.

Hereinafter, the present invention will be described on an assumption that a photosensitive glass is used as a glass substrate in which a crystal is precipitated and cuttable by etching. However, the glass substrate in the present embodiment is not limited to the photosensitive glass.

As described above, since the glass substrate is made of a glass in which a crystal is precipitated and cuttable by etching, the glass substrate can have a microscopic structure. Although not particularly limited, the microscopic structure preferably has at least one stereoscopic structure of a through hole, a hollowed-out structure, and a hollow structure.

The through hole is a hole-shaped structure formed in the substrate. The through hole mainly plays the following roles (1) and (2).
(1) A hole for inserting a terminal of an electronic component
(2) A hole for conduction between substrate layers

The hole for conduction between the substrate layers is also referred to as a via hole.

The via hole electrically connects conductor layers in the case where the number of layers of a circuit is two or more. The via hole is roughly classified into the following two types (A) and (B).
(A) A through hole via: a hole penetrating through all layers of the substrate
(B) An interstitial via: a hole penetrating through a part of the substrate

Examples of the interstitial via include a blind via (a hole penetrating through a surface and an inner layer of the substrate) and a buried via (a hole penetrating through the inner layer and the inner layer of the substrate).

The hollowed-out structure means a structure in which a certain portion of the substrate is cut from a surface to a certain depth and a specific portion of the substrate is hollowed out. The hollowed-out structure generally includes a structure which is also called a cavity or a counterbore. Further, the hollowed-out structure may be formed by hollowing out the surface of the substrate into any shape, and includes, for example, a spiral structure hollowed out in a spiral shape.

There are several possible roles of the hollowed-out structure, and examples thereof include the following (a) to (d).
(a) By hollowing out the structure, a contact area between the substrate and the wiring layer is reduced, and loss is improved (the detailed principle will be described later).
(b) A device is miniaturized by embedding a component inside the substrate.
(c) A position of the component is stabilized when the component is mounted.
(d) Only a part of a conductor portion (for example, a copper foil) of the inner layer is exposed.

The roles of the hollowed-out structure are not limited to the above (a) to (d).

The hollow structure is a tubular structure having a hollow interior. FIG. 2 is a diagram schematically illustrating the hollow structure. The hollow structure 20 illustrated in FIG. 2 has a glass substrate 21 and a cavity portion 22 therein. A cross-sectional shape of the hollow structure is generally a circular shape or a rectangular shape, but is not limited thereto.

The hollow structure is a structure adopted in, for example, a waveguide. The waveguide has a wall surface inside which is covered with a metal, and is used for transmission of electromagnetic waves. In FIG. 2, a structure in which a wall surface inside the cavity portion 22 is covered with a metal is a structure of the waveguide. The hollow structure has a hollow interior, and since air is a dielectric that causes dielectric loss, the hollow structure has characteristics of low loss and high-power transmission.

Applications of the hollow structure in the present embodiment are not limited to the waveguide.

Since the glass substrate can have the microscopic structure as described above, the circuit board according to the present embodiment can be applied to a high-frequency device having a microscopic hole shape such as a through hole, and is particularly suitable for large-scale production of these devices.

Common techniques for forming through holes include laser processing and cutting with a drill, but using these methods to produce substrates having through holes on a large scale requires a lot of cost and time. In this regard, the circuit board according to the present embodiment is suitable for large-scale production because etching can be used in a processing process of the glass substrate.

The glass substrate can be processed to form a deeper hollowed-out structure. Even with the current technique, a hollowed-out structure having a shallow depth can be achieved by a combination of photolithography and etching, but it is difficult with the current technique for a hollowed-out structure having a deeper depth. On the other hand, since the circuit board according to the present embodiment includes the glass substrate which can have a microscopic structure, the circuit board can have a deep hollowed-out structure.

A shape of the glass substrate is not particularly limited, and various shapes can be made depending on purposes and applications. For example, as illustrated in FIG. 1, the glass substrate may have a sheet shape including two main surfaces (the first main surface 2a and the second main surface 2b) facing each other, or may have a shape other than the sheet shape according to a product, an application, or the like to which the glass substrate is applied.

More specifically, the glass substrate may be a flat glass sheet having no warpage, or may be a curved glass sheet having a curved surface. A shape of the main surface is not particularly limited, and can be formed into various shapes such as a circular shape and a quadrangular shape.

In the case where the glass substrate has a sheet shape having two main surfaces facing each other, a plate thickness thereof is preferably 3 mm or less, more preferably 2 mm or less, and even more preferably 1 mm or less. In the case where the sheet thickness is within the above range, the entire thickness can be reduced when a circuit is formed by laminating the substrates, which is preferable. On the other hand, from a viewpoint of strength, the sheet thickness is preferably 0.05 mm or more, more preferably 0.1 mm or more, and even more preferably 0.2 mm or more.

Next, a reduction in loss of the glass substrate will be described. The glass substrate in the present embodiment has a dielectric loss tangent at 20° C. and 10 GHz of 0.0090 or less, and the circuit board including the glass substrate can achieve low transmission loss. There are no particular restrictions on methods for the reduction in loss of the glass substrate, but there are, for example, the following two methods. The first is a method of approaching from an aspect of material properties, and the second is a method of approaching from an aspect of structure.

In order to reduce the transmission loss from the aspect of the material properties, it is necessary to improve the dielectric loss tangent of the glass. Transmission loss of a signal in a high-frequency circuit board is generally known to be proportional to a frequency and a dielectric loss tangent of a substrate material.

Since the transmission loss is proportional to the frequency and the dielectric loss tangent of the substrate material, and the frequency increases in a high-frequency band, there is a strong need to further reduce loss in a circuit board for a high-frequency device. Therefore, in order to reduce loss, the dielectric loss tangent of the substrate material is required to be improved.

In order to improve the dielectric loss tangent of the glass, an alkali mixing effect is particularly effective. The alkali mixing effect is an effect of changing physical properties of the glass by mixing a plurality of kinds of alkali metal species instead of a single alkali metal species. As an alkali metal component used for a glass composition, three types, that is, Li, Na, and K are commonly used. That is, in a case of a glass containing a single alkali metal component in the glass composition, the dielectric loss tangent can be improved by mixing these three types of alkali metal components.

The dielectric loss tangent of the glass substrate at 20° C. and 10 GHz is preferably 0.0089 or less, more preferably 0.0088 or less, even more preferably 0.0087 or less, particularly preferably 0.0086 or less, and most preferably 0.0085 or less, from a viewpoint of improving dielectric characteristics. A lower limit of the dielectric loss tangent is not particularly limited, and is preferably 0.0005 or more, for example.

Further, relative permittivity of the glass substrate at 20° C. and 10 GHz is preferably 7.2 or less, more preferably 7.1 or less, even more preferably 7.0 or less, further even more preferably 6.95 or less, and particularly preferably 6.90 or less, from a viewpoint of improving dielectric characteristics. A lower limit of the relative permittivity is not particularly limited, and is preferably 3 or more, for example.

The dielectric loss tangent and the relative permittivity can be measured by a split post dielectric resonance method (SPDR method) using a network analyzer.

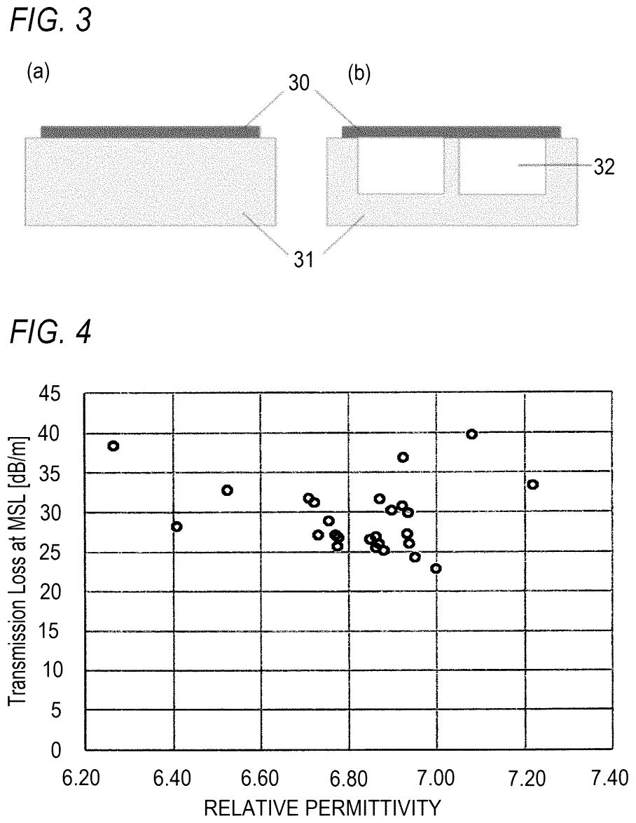

Further, in order to reduce the transmission loss from the aspect of the structure, it is preferable to reduce the contact area between the glass substrate and the wiring layer by forming a hollowed-out structure in the glass substrate. A schematic diagram of this structure is illustrated in FIG. 3. In FIG. 3, reference numeral 30 denotes a wiring layer, reference numeral 31 denotes a glass substrate, and reference numeral 32 denotes a hollowed-out portion which is cut by microfabrication, and these figures are cross-sectional views schematically illustrating a state in which a wiring layer is formed on a glass substrate.

(a) of FIG. 3 illustrates a state in which the wiring layer 30 is formed on the glass substrate 31 as usual. (b) of FIG. 3 illustrates a state in which the glass substrate 31 is subjected to microfabrication and a part of the glass substrate 31 is hollowed out. A reason why the reduction in loss can be achieved by such a hollowed-out structure is that the dielectric loss of the air itself is fairly small. That is, by adopting the hollowed-out structure, the reduction in loss can be achieved by replacing a portion where the material originally existed with air having a lower dielectric loss.

As described above, a processing technique and processing characteristics of a material are important for achieving the reduction in loss by the hollowed-out structure. Since in the glass substrate in the present embodiment, the crystal is precipitated and cuttable by etching, a hollowed-out structure can be formed, and a reduction in loss can be achieved.

### Wiring Layer

The circuit board according to the present embodiment may include a wiring layer. The wiring layer is a layer including a wiring formed of a conductor and serves to electrically connect various elements. The first wiring layer 3 in FIG. 1 constitutes a signal wiring, and the second wiring layer 4 constitutes a ground wiring.

Further, the wiring layer may be formed inside the glass substrate or on at least one main surface of the glass substrate.

A thickness of the wiring layer is generally set according to a condition, such as an application or a frequency band, when the circuit board is used. However, the thickness of the wiring layer is usually 0.1 μm or more, preferably 0.5 μm or more, more preferably 1 μm or more, and is usually 100 μm or less, preferably 80 μm or less, and more preferably 60 μm or less, from a viewpoint of practical use. Further, the thickness of the wiring layer is usually 0.1 μm to 100 μm, preferably 0.5 μm to 80 μm, and more preferably 1 μm to 60 μm.

A structure of the wiring layer is not limited to a single layer structure, and may have a multi-layer structure such as a laminated structure of a titanium layer and a copper layer.

### Others

The circuit board according to the present embodiment may include any device or component for use as a high-frequency device. For example, it is preferable that the circuit board includes at least one of a passive device and an active device. For example, a radio frequency (RF) circuit may include a key passive device (an antenna, a frequency filter, a duplexer, a diplexer, or the like), an active device (a switch, a phase shifter, or the like), and a general circuit component (passive: a capacitor, an inductor, a resistor, active: a transistor, a diode, an IC, an LSI, or the like). Further, a packaging material such as a mold or a resist may be provided as a mounting material.

### Manufacturing Method of Circuit Board

A manufacturing method of the circuit board for the high-frequency device according to the present embodiment will be described. The manufacturing method includes at least a glass production step, a glass substrate processing step, and a wiring layer formation step. An order of these processes is not clearly defined. The order may be changed as necessary, or the same step may be repeated again. For example, a plurality of specific steps such as glass substrate processing→wiring layer formation→glass substrate processing may be included or may not be included.

### Glass Production Step

In this step, a raw material blended so as to have a desired glass composition is melt-molded to thereby produce an amorphous glass. A method of melting and molding is not particularly limited, and for example, a glass raw material prepared by blending a glass raw material is put into a platinum crucible, and put into an electric furnace heated to a melting temperature to melt the raw material.

In the case where the melting temperature is too low, the raw material does not melt. Therefore, when a temperature at which a high-temperature viscosity η of a glass melt is log η=2 is T₂, the melting temperature is preferably T₂ or more, more preferably (T₂+10° C.) or more, even more preferably (T₂+20° C.) or more, further even more preferably (T₂+30° C.) or more, particularly preferably (T₂+40° C.) or more, and most preferably (T₂+50° C.) or more.

On the other hand, in the case where the melting temperature is too high, a load is applied to equipment such as an electric furnace. Therefore, the melting temperature is preferably (T₂+500° C.) or less, more preferably (T₂+450° C.) or less, even more preferably (T₂+400° C.) or less, particularly preferably (T₂+350° C.) or less, and most preferably (T₂+300° C.) or less. When the raw material is sufficiently melted, the raw material is homogenized by, for example, stirring with a stirrer, and the resultant is then allowed to stand for defoaming. At this time, a temperature of the electric furnace may be increased in order to increase homogeneity and defoaming performance as necessary.

The obtained molten glass is poured into a metal mold (for example, a SUS plate) at room temperature, held at a temperature of a glass transition point for approximately 1 hour to 2 hours, for example, and then annealed to room temperature to thereby obtain a glass block of the amorphous glass. In the case where an annealing rate at this time is too fast, residual stress remains in the glass, causing breakage and cracks. Therefore, the annealing rate is preferably 100° C./min or less, and in the following order of preference, 80° C./min or less, 60° C./min or less, 40° C./min or less, 20° C./min or less, and 10° C./min or less.

On the other hand, when the annealing rate is too slow, annealing takes too much time, resulting in poor efficiency in production. Therefore, the annealing rate is preferably 0.01° C./min or more, and in the following order of preference, 0.05° C./min or more, 0.1° C./min or more, 0.2° C./min or more, 0.4° C./min or more, 0.6° C./min or more, 0.8° C./min or more, and 1° C./min or more.

Further, the obtained glass block is subjected to processing such as cutting, grinding, polishing, and the like as necessary to thereby mold the glass block into a desired substrate shape.

As a polishing treatment of the surface of the substrate, for example, mechanical polishing using an abrasive containing cerium oxide, colloidal silica, or the like as a main component, and a polishing pad; chemical mechanical polishing using a polishing slurry containing an abrasive, and an acidic liquid or an alkaline liquid as a dispersion medium, and a polishing pad; or chemical polishing using an acidic liquid or an alkaline liquid as an etching solution can be applied. These polishing treatments are applied according to surface roughness of a glass sheet to be used as a material for the glass substrate. For example, preliminary polishing and finish polishing may be applied in combination. Further, an end surface of the glass substrate is preferably chamfered in order to prevent breakage, cracking, and chipping of the glass substrate caused by the end surface during a process flow. A form of chamfering may be any of C chamfering, R chamfering, thread chamfering, or the like.

As described above, the amorphous glass can be formed into a desired shape from a molten state. Therefore, as compared with a process of molding a firing powder or slurry as in a case of a ceramic or the like, or a process of cutting into a desired shape after manufacturing an ingot as in a case of synthetic quartz, the amorphous glass has an advantageous in that it is easy to mold or increase the area, and can be manufactured at low cost.

### Glass Substrate Processing Step

This step includes a crystal precipitation step and an etching step. That is, this step includes a step of processing the glass substrate by removing a precipitated crystal by etching after precipitating a crystal capable of etching in the glass.

In the case where a photosensitive glass is used, examples of a method of precipitating a crystal include a method of performing exposure treatment and heat treatment. Further, a method of locally crystallization by laser irradiation or the like is also included. A method of using the photosensitive glass and precipitating crystal by exposure treatment and heat treatment will be described below. However, the manufacturing method according to the present embodiment is not limited to such a method.

In the crystal precipitation step, first, the photosensitive glass is subjected to exposure treatment. At this time, the photosensitive glass may be processed into a desired size so as to fall within a standard of an exposure apparatus. Further, polishing may be performed on a surface requiring high accuracy. Then, an optical mask on which a desired microfabrication pattern is formed is prepared, and the optical mask is superposed on the glass and irradiated with ultraviolet rays. As the optical mask, an optical mask used in general ultraviolet exposure lithography can be used.

As the exposure apparatus, for example, a product name “MA-1200” manufactured by Japan Science Engineering Co., Ltd. may be used. In the case where an exposure amount is too high, portions other than a desired portion may be exposed, and a reaction may proceed more than necessary. Therefore, the exposure amount is preferably 30 J/cm² or less.

The exposure amount is, in the following order of preference, 28 J/cm² or less, 26 J/cm² or less, 24 J/cm² or less, 22 J/cm² or less, 20 J/cm² or less, 18 J/cm² or less, 16 J/cm² or less, 14 J/cm² or less, 12 J/cm² or less, and 10 J/cm² or less.

On the other hand, in the case where the exposure amount is too low, the desired portion may not react sufficiently and the reaction may not proceed sufficiently. Therefore, the exposure amount is preferably 0.01 J/cm² or more, and in the following order of preference, 0.02 J/cm² or more, 0.04 J/cm² or more, 0.06 J/cm² or more, 0.08 J/cm² or more, and 0.1 J/cm² or more.

Subsequently, the exposed photosensitive glass is subjected to heat treatment to precipitate a crystal. The heat treatment is generally performed in two stages. A first-stage heat treatment is intended to precipitate a component that serves as a crystal nucleus in the glass. Therefore, a heat treatment temperature is preferably in a temperature range in which a crystal nucleation rate increases in the glass composition. For example, the heat treatment temperature is within a range of Tg±150° C.

Further, a holding time in a first temperature range is, in the following order of preference, 15 minutes or more, 30 minutes or more, 45 minutes or more, 1 hour or more, 1 hour and 15 minutes or more, 1 hour and 30 minutes or more, 1 hour and 45 minutes or more, 2 hours or more, 2 hours and 15 minutes or more, 2 hours and 30 minutes or more, 2 hours and 45 minutes or more, 3 hours or more, 3 hours and 15 minutes or more, 3 hours and 30 minutes or more, 3 hours and 45 minutes or more, and 4 hours or more. In the case where the holding time is within the above range, nucleation is likely to proceed sufficiently. On the other hand, from a viewpoint of manufacturability, the holding time is, in order of preference, 15 hours or less, 14 hours or less, 13 hours or less, 12 hours or less, 11 hours or less, and 10 hours or less.

A second-stage heat treatment is intended to precipitate a crystal around the nucleus in the glass. The heat treatment temperature is preferably in a temperature range in which a crystal growth rate of the crystal increases. Specifically, the heat treatment is performed in a range of 20° C. or more and 300° C. or less with respect to the heat treatment temperature in the first stage.

The holding time in a second temperature range is, in the following order of preference, 15 minutes or more, 30 minutes or more, 45 minutes or more, 1 hour or more, 1 hour and 15 minutes or more, 1 hour and 30 minutes or more, 1 hour and 45 minutes or more, 2 hours or more, 2 hours and 15 minutes or more, 2 hours and 30 minutes or more, 2 hours and 45 minutes or more, and 3 hours or more. In the case where the holding time is within the above range, the crystal growth is likely to proceed sufficiently.

On the other hand, from the viewpoint of manufacturability, the holding time is, in order of preference, 15 hours or less, 14 hours or less, 13 hours or less, 12 hours or less, 11 hours or less, and 10 hours or less.

Subsequently, the precipitated crystal is cut by etching processing. In the case where an etching rate of a crystal portion is higher than that of a glass portion, the crystal portion can be removed, and the glass can be processed. Here, the etching rate refers to a value obtained by the equation (1) described below when the glass is reacted with an etching solution. At this time, a type of etching solution is not particularly limited.

In a case of the photosensitive glass, HF is generally used as the etching solution. A mixed acid of HF and another acid (HCl, HNO₃, H₂SO₄, or the like) may be used. Other acids (HCl, HNO₃, H₂SO₄, or the like) may be used without using HF. If necessary, an alkaline solution may be used.

An etching method is not particularly limited. Examples of the etching method include a DIP method in which a glass is immersed in an etching solution, and a spraying method in which an etching solution is blown onto a glass. In order to promote the reaction between the solution and the glass, stirring, shaking, or the like may be used as necessary.

$$\begin{matrix}[ Math . 1 ] & \\ etching rate ( \frac{µm}{min} ) = \frac{weight loss ( g ) \times thickness of glass before testing ( µm )}{weight of glass before testing ( g ) \times test time ( min )} & ( 1 )\end{matrix}$$

As a specific method, in the case of the photosensitive glass, a glass portion etching rate can be obtained by the above equation (1) by immersing a glass sample having a length of 30 mm×a width of 20 mm and a thickness of 0.5 mmt in 55 ml of an etching solution at 40° C. containing HF of 5 mass % and HNO₃ of 0.7 mass % for 4 minutes.

The glass portion etching rate obtained under this condition is preferably 2.75 or less from a viewpoint of properties of microfabrication. In the case where the glass portion etching rate is 2.75 or less, the glass portion can be prevented from being etched more than necessary during etching, and the microscopic structure can be easily controlled.

The glass portion etching rate is, in the following order of preference, 2.70 or less, 2.65 or less, 2.60 or less, 2.55 or less, 2.50 or less, 2.45 or less, particularly 2.40 or less. Although there is no problem in the case where the glass portion etching rate is small, the glass portion etching rate is preferably 0.1 or more, for example.

From the viewpoint of properties of microfabrication, it is preferable that a value of an etching rate selectivity represented by the equation (2) described below is large. The etching rate selectivity indicates a ratio obtained by dividing an etching rate (a crystal portion etching rate) of a crystallized portion by an etching rate (a glass portion etching rate) of a glass portion. In the case where the value of the etching rate selectivity is large, the crystal portion is selectively removed with respect to the glass, and microfabrication can be performed on the glass.

The etching rate selectivity is calculated based on the following equation (2) by obtaining an etching rate (a crystal portion etching rate) obtained by etching a glass on which a crystal is precipitated, and an etching rate (a glass portion etching rate) obtained by etching a glass on which no crystal is precipitated, respectively.

$$\begin{matrix}[ Math . 2 ] & \\ etching rate selectivity = \frac{crystal portion etching rate}{glass portion etching rate} & ( 2 )\end{matrix}$$

For example, as a specific method, a method of obtaining the etching rate selectivity in the case of the photosensitive glass will be described. A method of calculating the glass portion etching rate is as described above. The crystal portion etching rate is calculated based on the above equation (1) by subjecting the glass sample having a length of 30 mm×a width of 20 mm, and a thickness of 0.5 mmt to etching after exposure treatment and heat treatment. Specific treatment conditions are illustrated below.

### (i) Exposure Treatment

By using an exposure apparatus (for example, the product name “MA-1200” manufactured by Japan Science Engineering Co., Ltd.), the entire flat glass is exposed so as to have an exposure amount of 15 J/cm².

### (ii) Heat Treatment

The two-stage heat treatment is performed. Conditions for the first-stage heat treatment are, for example, heat treatment at 485° C. for 5 hours. Conditions for the second-stage heat treatment can be determined by, for example, the following method. First, a crystallization peak is confirmed using a differential thermal analysis (DTA) apparatus (for example, Thermoplus TG8120 manufactured by Rigaku Corporation). The heat treatment is performed in a range of −150° C. to −50° C. from a temperature at which the crystallization peak is confirmed, for a heat treatment time in a range of 1 hour to 3 hours. At this time, the same treatment is performed on a glass having the same composition not subjected to exposure, and a range in which it can be confirmed that no crystal is precipitated is set as a heat treatment condition.

A method for confirming the crystal precipitation is, for example, a method by microscope observation. In the case where the glass portion is observed with a microscope using epi-illumination, light scattering occurs in a portion where the crystal is precipitated, and thus the crystal portion appears bright while the glass portion is dark. Based on brightness and darkness, presence or absence of crystal precipitation can be confirmed.

### (iii) Etching

The glass sample is immersed in 55 ml of the etching solution at 40° C. containing 5 mass % of HF and 0.7 mass % HNO₃ for 4 minutes.

For example, after performing the above treatments, the value obtained by the above equation (1) is set as the crystal portion etching rate.

For example, the etching rate selectivity of the photosensitive glass obtained by the above method is preferably 3 or more from the viewpoint of properties of microfabrication. In the case where the etching rate selectivity ratio is 3 or more, selective cutting is possible, and the microscopic structure can be controlled.

The etching rate selectivity is, in the following order of preference, 4 or more, 5 or more, 6 or more, 7 or more, 8 or more, 9 or more, 10 or more, 11 or more, 12 or more, 13 or more, 14 or more, 15 or more, 16 or more, 17 or more, 18 or more, 19 or more, and particularly preferably 20 or more. Further, an upper limit of the etching rate selectivity is not particularly limited, and is generally 50 or less, 45 or less, and particularly preferably 40 or less.

Types of etching are roughly classified into two types: dry etching and wet etching. The dry etching is a method of etching a material by a reactive gas (etching gas), an ion, and a radical, and wet etching is a method of etching a material using a liquid chemical.

When both of them are compared, in general, the dry etching allows processing with a higher aspect ratio (ratio of etching depth and width) and has a higher degree of freedom in processing, but requires expensive equipment and may use dangerous reactive gases. On the other hand, the wet etching is relatively inexpensive compared with the dry etching, and is superior in terms of processing depth controllability and uniformity.

Methods for removing the crystal other than etching include laser processing and cutting processing such as drilling, but the etching processing has an advantage of being more suitable for mass production. Further, the etching processing is also superior in terms of processing a special 3D shape.

If necessary, re-polishing may be performed after the etching processing. This is because the surface of the glass substrate may be roughened through the heat treatment and the etching step. A re-polishing step may be the same as the polishing step performed after producing the glass. In the case where the polishing steps are the same, the abrasive and the polishing pad to be used can be unified, and thus a load on a manufacturing side can be reduced.

### Wiring Layer Formation Step

This step is a step of forming a wiring layer on the glass substrate processed as described above. As illustrated in FIG. 1, the wiring layer may be formed on at least one main surface of the glass substrate, or may be formed inside the glass substrate.

A method of forming the wiring layer is not particularly limited, and various known forming methods such as a printing method using a conductive paste, a dipping method, a plating method, a vapor deposition method, and a sputtering method can be applied. Among them, the plating method is preferable from viewpoints of cost and mass productivity. The plating method will be described below. However, the wiring layer formation step in the present embodiment is not limited to the plating method.

The metal species to be plated is not particularly limited, and commonly used metals can be used, and examples thereof include gold, silver, copper, nickel, cobalt, tin, and platinum group (palladium, platinum, rhodium, and ruthenium). Among these, since a plating technique is generally established, it is preferable to use at least one selected from the group consisting of gold, silver, copper, nickel, and cobalt. Among these, in the present embodiment, since a metal having conductivity is preferable, a metal constituting the wiring layer is preferably at least one selected from the group consisting of gold, silver, and copper. From the viewpoint of cost, copper is particularly preferable.

Examples of a method of plating include electroless plating and electrolytic plating. The electroless plating allows plating with a relatively uniform film thickness can be performed. On the other hand, the electrolytic plating is suitable for a purpose of forming a thicker film. Therefore, in general, first, a plating treatment is performed by a combination of the electroless plating at first and subsequent the electrolytic plating. However, this plating step is not limited to a combination of both methods, and any one of the methods may be used as necessary.

In the plating step, in particular, when plating is performed on a glass substrate in which a processing such as via hole is performed and has a microscopic structure such as a fairly thin structure or a fairly narrow structure, a sufficient amount of plating solution needs to be supplied to a portion where the plating treatment is performed. Therefore, it is preferable to stir, vibrate, oscillate, bubble, or combine these treatments as necessary.

### Applications

Applications of the circuit board according to the present embodiment are not particularly limited as long as the circuit board is used for a high-frequency device.

Further, the circuit board according to the present embodiment can be used for transmitting a signal having a frequency of 1 GHz to 100 GHz.

In FIG. 1, the first wiring layer 3 and the second wiring layer 4 form a microstrip line as an example of the transmission line. Other examples of the transmission line include a strip line, a coplanar line, a slot line, a waveguide, a substrate integrated waveguide (SIW).

A microstrip line is the most common transmission line. On the other hand, in the case where the microstrip line is a high-frequency band of about 10 GHz or more, the loss increases and the use is complicated. On the other hand, SIW exhibits relatively low loss particularly in a high-frequency band as compared with a known structure such as a microstrip line. Further, the SIW may have not only a through hole but also a hollowed-out structure in the substrate depending on the application. The present invention is suitable as a substrate including such a transmission line.

Further, by applying an appropriate design to the circuit board according to the present embodiment, a function of the transmission line (wiring) can also have a function of a passive device such as a filter, an antenna, a duplexer, and a diplexer. For example, as a form of a filter which is one of high-frequency devices, a configuration using a transmission line such as a waveguide, an SIW, or a microstrip line is known. In addition, a configuration in which a microstrip line is applied to an antenna application is also known.

In addition, as the frequency increases, there is an increasing need for miniaturization of a package. Further, improvement in high-frequency performance by forming a hollowed-out structure, and the like are also expected to be required in a high-frequency band. Therefore, 3D processability is required in a high-frequency band, and the circuit board according to the present embodiment can be preferably applied to such a high-frequency device.

### EXAMPLES

Examples will be described below, and the present invention is not limited to these examples.

Glass 1 to glass 9 and glass 23 to glass 27 are working examples, and glass 10 to glass 22 are comparative examples.

### Transmission Loss Calculation Example

In order to confirm an influence of dielectric characteristics of a glass substrate material on transmission loss of a high-frequency signal, transmission loss of a transmission line in a simplified model was calculated.

The transmission line was a microstrip line (MSL). Examples of the transmission line that is actually required to have the 3D processability include a substrate integrated waveguide (SIW) and a waveguide. On the other hand, in this example, focusing on the photosensitive glass (glass obtained by precipitating a crystal that can be removed by etching) as the substrate material, the influence of the dielectric characteristics of the glass substrate on the transmission loss when the most common microstrip line (MSL) was used as the transmission line was confirmed.

TXLINE (manufactured by cadence) was used as an analysis software. An analysis model was as follows.

A copper wiring layer formed on one main surface of the glass substrate was defined to have a wiring width (illustrated in Table 1 to Table 4) in which characteristic impedance of the microstrip line was 50Ω, and transmission loss at 10 GHz was calculated. Further, a thickness of a glass as a dielectric layer was 0.125 mm, and a thickness of the copper wiring as a conductor layer was 18 μm. A surface roughness of the copper wiring layer was set to be sufficiently smooth as a skin effect was not a problem. Further, relative permittivity (Dk) and a dielectric loss tangent (Df) of the glass at 20° C. and 10 GHz were used for calculation analysis. The relative permittivity and the dielectric loss tangent of the glass at 10 GHz used in this calculation are measured values measured at a measurement temperature of 20° C. using a split post dielectric resonance method (SPDR method) on the actually produced glass.

The photosensitive glass used in this calculation is a glass in which a Li₂SiO₃ crystal is precipitated, and the Li₂SiO₃ crystal can be cut by hydrofluoric acid etching.

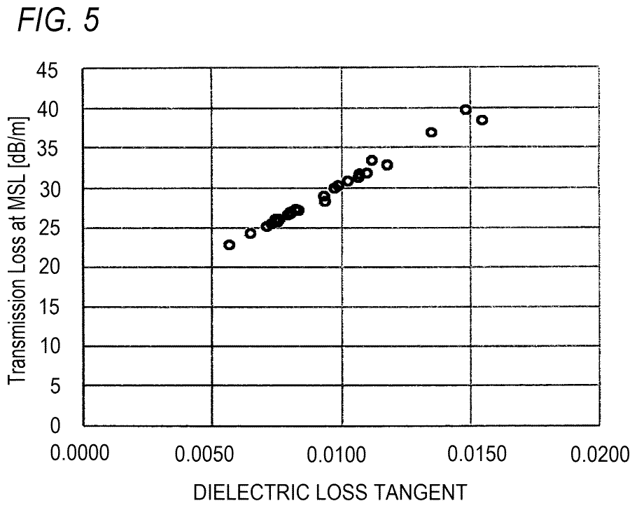

In a composition of each glass, a ratio of Li, Na, and K as the alkali species was appropriately adjusted within a range in which the Li₂SiO₃ crystal was precipitated. The calculated transmission loss is illustrated in Table 1 to Table 4. FIG. 4 and FIG. 5 illustrate a magnitude of the transmission loss with respect to the relative permittivity and the dielectric loss tangent of the glass substrate.

TABLE 1

| | Glass 1 | Glass 2 | Glass 3 | Glass 4 | Glass 5 | Glass 6 | Glass 7 |
|---|---|---|---|---|---|---|---|
| Dk @ 10 GHz | 6.88 | 6.86 | 6.78 | 6.87 | 6.78 | 6.86 | 6.85 |
| Df @ 10 GHz | 0.0071 | 0.0073 | 0.0075 | 0.0076 | 0.0081 | 0.0081 | 0.0079 |
| Transmission Loss | 25 | 25 | 26 | 26 | 27 | 27 | 27 |
| @ 10 GHz (dB/m) | | | | | | | |
| Wiring width (μm) | 154 | 154 | 156 | 154 | 156 | 154 | 154 |

TABLE 2

| | Glass 8 | Glass 9 | Glass 10 | Glass 11 | Glass 12 | Glass 13 | Glass 14 |
|---|---|---|---|---|---|---|---|
| Dk @ 10 GHz | 6.77 | 6.73 | 6.71 | 7.22 | 7.08 | 6.93 | 6.87 |
| Df @ 10 GHz | 0.0083 | 0.0084 | 0.0110 | 0.0112 | 0.0149 | 0.0135 | 0.0107 |
| Transmission Loss | 27 | 27 | 32 | 33 | 40 | 37 | 32 |
| @ 10 GHz (dB/m) | | | | | | | |
| Wiring width (μm) | 156 | 157 | 157 | 147 | 150 | 153 | 154 |

TABLE 3

| | Glass 15 | Glass 16 | Glass 17 | Glass 18 | Glass 19 | Glass 20 | Glass 21 |
|---|---|---|---|---|---|---|---|
| Dk @ 10 GHz | 6.93 | 6.72 | 6.92 | 6.90 | 6.53 | 6.27 | 6.76 |
| Df @ 10 GHz | 0.0097 | 0.0107 | 0.0102 | 0.0099 | 0.0118 | 0.0155 | 0.0093 |
| Transmission Loss | 30 | 31 | 31 | 30 | 33 | 38 | 29 |
| @ 10 GHz (dB/m) | | | | | | | |
| Wiring width (μm) | 153 | 157 | 153 | 153 | 161 | 167 | 156 |

TABLE 4

| | Glass 22 | Glass 23 | Glass 24 | Glass 25 | Glass 26 |
|---|---|---|---|---|---|
| Dk @ 10 GHz | 6.41 | 7.00 | 6.95 | 6.94 | 6.93 |
| Df @ 10 GHz | 0.0094 | 0.0057 | 0.0065 | 0.0075 | 0.0082 |
| Transmission | 28 | 23 | 24 | 26 | 27 |
| Loss @ 10 GHz | | | | | |
| (dB/m) | | | | | |
| Wiring width | 164 | 151 | 152 | 152 | 153 |
| (μm) | | | | | |

FIG. 4 is a graph plotting the relative permittivity of the glass substrate on a horizontal axis and the transmission loss on a vertical axis. FIG. 5 is a graph plotting the dielectric loss tangent of the glass substrate on a horizontal axis and the transmission loss on a vertical axis. From these figures, it can be seen that contribution of the dielectric loss tangent to the improvement of the transmission loss is greater than that of the relative permittivity. Therefore, by using a glass substrate having a low dielectric loss tangent, a circuit board for a high-frequency device having less transmission loss can be produced.

Although various embodiments have been described above with reference to the drawings, it is needless to say that the present invention is not limited to such examples. It is apparent to those skilled in the art that various changes and modifications can be conceived within the scope of the claims, and it is also understood that such changes and modifications belong to the technical scope of the present invention. Further, the components described in the above embodiment may be combined in any manner without departing from the spirit of the invention.

The present application is based on Japanese Patent Application No. 2021-093784 filed on Jun. 3, 2021, the contents of which are incorporated herein by reference.

### REFERENCE SIGNS LIST

1: circuit board
2, 21, 31: glass substrate
2a, 2b: main surface
3, 4, 30: wiring layer
20: hollow structure
22: cavity portion
32: hollowed-out portion

1. A circuit board for a high-frequency device, comprising:
a glass substrate in which a crystal is precipitated and cuttable by etching, and which has a dielectric loss tangent at 20° C. and 10 GHz of 0.0090 or less.

2. The circuit board according to claim 1, wherein
a signal having a frequency of 1 GHz to 100 GHz is transmitted.

3. The circuit board according to claim 1, wherein
the glass substrate has at least one stereoscopic structure of a through hole, a hollowed-out structure, and a hollow structure.

4. The circuit board according to claim 1, further comprising:
a transmission line.

5. The circuit board according to claim 1, further comprising:
at least one of a passive device and an active device.

6. A high-frequency device comprising the circuit board according to claim 1.
